(19) United States
(12) Patent Application Publication
(10) Pub. No.: US 2024/0321851 A1
(43) Pub. Date: Sep. 26, 2024

(54) SEMICONDUCTOR PACKAGES AND METHOD FOR MANUFACTURING THE SAME

(71) Applicant: SAMSUNG ELECTERONICS CO., LTD., Suwon-si (KR)

(72) Inventors: CHOONGBIN YIM, Suwon-si (KR); Jongkook Kim, Suwon-si (KR); Chengtar Wu, Suwon-si (KR)

(21) Appl. No.: 18/506,346

(22) Filed: Nov. 10, 2023

(30) Foreign Application Priority Data
Mar. 3, 2023 (KR) 10-2023-0028502

(51) Int. Cl. H01L 25/18; H01L 21/56; H01L 23/00; H01L 25/00; H10B 80/00

(52) U.S. Cl. CPC H01L 25/18; H01L 21/568; H01L 24/05; H01L 24/08; H01L 24/13; H01L 24/16; H01L 24/19; H01L 24/20; H01L 24/32; H01L 24/73; H01L 24/80; H01L 24/83; H01L 24/92; H01L 24/95; H01L 25/50; H10B 80/00; H01L 2224/0557; H01L 2224/05611; H01L 2224/05616; H01L 2224/05624; H01L 2224/05639; H01L 2224/05644; H01L 2224/05647; H01L 2224/05655; H01L 2224/05666; H01L 2224/08145; H01L 2224/13111; H01L 2224/13116; H01L 2224/13139; H01L 2224/13147; H01L 2224/13155; H01L 2224/16145; H01L 2224/19; H01L 2224/214; H01L 2224/215; H01L 2224/32145; H01L 2224/73204; H01L 2224/80006; H01L 2224/80357; H01L 2224/80379; H01L 2224/80896; H01L 2224/83005; H01L 2224/83862; H01L 2224/92125; H01L 2224/95001; H01L 2924/01013; H01L 2924/01022; H01L 2924/01028; H01L 2924/01029; H01L 2924/0105; H01L 2924/01074; H01L 2924/01079; H01L 2924/0504; H01L 2924/05442; H01L 2924/059

(57) ABSTRACT

A semiconductor package includes: a redistribution layer structure; a first semiconductor die and a second semiconductor die disposed on the redistribution layer structure; a bridge die disposed on the first semiconductor die and the second semiconductor die and that electrically connects the first semiconductor die and the second semiconductor die to each other; and a molding material disposed on the redistribution layer structure and that molds of the first semiconductor die, the second semiconductor die, and the bridge die. A bottom surface of the first semiconductor die and a bottom surface of the second semiconductor die are coplanar with an upper surface of the redistribution layer structure.

### CROSS-REFERENCE TO RELATED APPLICATION

This application claims priority under 35 U.S.C. § 119 from Korean Patent Application No. 10-2023-0028502, filed in the Korean Intellectual Property Office on Mar. 3, 2023, the contents of which are herein incorporated by reference in their entirety.

### TECHNICAL FIELD

Embodiments of the present disclosure are directed to a semiconductor package and a manufacturing method thereof.

### DISCUSSION OF THE RELATED ART

In a semiconductor package that includes a plurality of semiconductor chips disposed side by side, the plurality of semiconductor chips must be electrically connected to transmit and receive signals to and from each other. For this purpose, conventionally, a redistribution layer (RDL) structure and a bridge structure are disposed under the plurality of semiconductor chips so that the I/O of the normal pitch of the semiconductor chips is electrically connected to the redistribution layer structure to send and receive signals, and the i/O of a fine pitch of the semiconductor chips sends and receives signals through the bridge structure.

However, according to a conventional art, since the bridge structure is disposed under a plurality of semiconductor chips, to include a through silicone via (TSV) in the bridge structure, a process of forming the through silicon via (TSV) in the bridge structure must be additionally performed, the bridge structure must be separately molded to protect the bridge structure, the first redistribution layer structure is required on the bridge structure, and the second redistribution layer structure is required under the bridge structure. Thus, more layers of the redistribution layer structure must be formed during the semiconductor package manufacturing process, and there is a risk of yield reduction and consequently cost increase.

### SUMMARY

An embodiment provides a semiconductor package and a manufacturing method of a semiconductor package, in which through silicon vias (TSVs) are formed in the semiconductor chips rather than the bridge die by disposing the bridge die on the semiconductor chips, the bridge structure is not separately molded, one redistribution layer structure is included in the bottom surface of the semiconductor chips, and bottom surfaces of the semiconductor chips are coplanar with an upper surface of the redistribution layer structure.

A semiconductor package according to an embodiment includes a redistribution layer structure; a first semiconductor die and a second semiconductor die disposed on the redistribution layer structure; a bridge die disposed on the first semiconductor die and the second semiconductor die and that electrically connects the first semiconductor die and the second semiconductor die to each other; and a molding material that molds the first semiconductor die, the second semiconductor die, and the bridge die onto the redistribution layer structure. A bottom surface of the first semiconductor die and a bottom surface of the second semiconductor die are coplanar with an upper surface of the redistribution layer structure.

The first semiconductor die and the second semiconductor die may exchange signals through the bridge die.

The bridge die may be disposed on a part of an upper surface of the first semiconductor die and a part of an upper surface of the second semiconductor die.

The redistribution layer structure may include a plurality of redistribution vias, the first semiconductor die and the second semiconductor die may include a plurality of connection pads at a lowest level, and each redistribution via of an uppermost level of a plurality of redistribution vias may be directly bonded with a corresponding connection pad of the plurality of connection pads.

The redistribution layer structure may include a plurality of redistribution vias, and an uppermost width of each redistribution via of the plurality of redistribution vias may be less than a lowermost width thereof.

The first semiconductor die and the second semiconductor die may each include an application processor (AP).

The bridge die may include a memory semiconductor.

A semiconductor package according to an embodiment includes: a redistribution layer structure; a first semiconductor die and a second semiconductor die disposed on the redistribution layer structure; an interconnection structure disposed on the first semiconductor die and the second semiconductor die; a bridge die disposed on the interconnection structure, where the interconnection structure electrically connects the bridge die and the first semiconductor die and the bridge die and the second semiconductor die, and the bridge die electrically connects the first semiconductor die and the second semiconductor die to each other; and a molding material disposed on the redistribution layer structure and that molds the first semiconductor die, the second semiconductor die, and the bridge die. Bottom surfaces of the first semiconductor die and the second semiconductor die are coplanar with an upper surface of the redistribution layer structure.

The interconnection structure may include a micro bump.

The interconnection structure may include an insulating member that surrounds the micro bump.

The insulating member may include a molded under-fill (MUF).

The interconnection structure may include a plurality of first bonding pads and a first insulation layer disposed on upper surfaces of the first semiconductor die and the second semiconductor die; and a plurality of second bonding pads and a second insulation layer disposed on a bottom surface of the bridge die.

Each first bonding pad of the plurality of first bonding pads may be directly bonded to a corresponding second bonding pad of the plurality of second bonding pads.

The first bonding pad and the second bonding pad may each include copper.

The first insulation layer may be directly bonded with the second insulation layer.

The first insulation layer and the second insulation layer may each include at least one of a silicon oxide, a silicon nitride, or a silicon oxynitride.

The first semiconductor die and the second semiconductor die may each include a plurality of through silicon vias (TSVs), respectively, and the plurality of through silicon vias may electrically connect the interconnection structure and the redistribution layer structure.

A manufacturing method of a semiconductor package according to an embodiment includes: attaching a first semiconductor die and a second semiconductor die side by side on a carrier; molding the first semiconductor die and the second semiconductor die on the carrier; bonding a bridge die onto the first semiconductor die and the second semiconductor die; molding the bridge die; and forming a redistribution layer structure on bottom surfaces of the first semiconductor die and the second semiconductor die. The bottom surface of the first semiconductor die and the second semiconductor die are coplanar with an upper surface of the redistribution layer structure.

Bonding the bridge die on the first semiconductor die and the second semiconductor die may be performed by hybrid bonding.

Removing the carrier and performing a probe test may be further included before forming the redistribution layer structure on the bottom surfaces of the first semiconductor die and the second semiconductor die.

According to an embodiment, the bridge die that electrically connects the first semiconductor die and the second semiconductor die to each other is disposed on the upper surface of the first semiconductor die and the second semiconductor die, and the redistribution layer structure is disposed on the bottom surface of the first semiconductor die and the second semiconductor die so that the bottom surface of the first semiconductor die and the second semiconductor die and the upper surface of the redistribution layer structure are coplanar.

Accordingly, a through silicon via (TSV) is not formed in the bridge die, but is formed in the semiconductor chips, and one redistribution layer structure is included on the bottom surface of the semiconductor chips.

On the redistribution layer structure, since the first semiconductor die, the second semiconductor die, and the bridge die are simultaneously molded by the molding material, the bridge structure is not separately molded.

Accordingly, in a manufacturing process of a semiconductor package, a yield is increased and a cost is reduced.

### BRIEF DESCRIPTION OF THE DRAWINGS

FIG. 1 is a cross-sectional view of a semiconductor package in which a bridge die is electrically and physically connected to a first semiconductor die and a second semiconductor die thereunder by a connection member.

FIG. 2 is a cross-sectional view of a semiconductor package in which a bridge die is electrically and physically connected to a first semiconductor die and a second semiconductor die thereunder by hybrid bonding.

FIG. 3 illustrates a step of mounting a first semiconductor die and a second semiconductor die on a first carrier as a step of a semiconductor package manufacturing method. FIG. 3 to FIG. 5 and FIG. 7 to FIG. 14 are cross-sectional views that illustrate steps of a manufacturing method of a semiconductor package of FIG. 1.

FIG. 4 illustrates a step of molding a first semiconductor die and a second semiconductor die on a first carrier.

FIG. 5 illustrates a step of mounting a bridge die on a first semiconductor die and a second semiconductor die by using a connecting member.

FIG. 6 illustrates a step of bonding a bridge die on a first semiconductor die and a second semiconductor die by performing hybrid bonding as one of steps of a semiconductor package manufacturing method. Other steps of a semiconductor package manufacturing method of FIG. 2 are substantially similar to steps of a semiconductor package manufacturing method shown and described or FIG. 3 to FIG. 5 and FIG. 7 to FIG. 14.

FIG. 7 illustrates a step of molding a first semiconductor die, a second semiconductor die, and a bridge die on a first carrier.

FIG. 8 illustrates a step of planarizing an upper surface of a molding material.

FIG. 9 illustrates a step of removing (de-bonding) a first carrier.

FIG. 10 illustrates a step of bonding a second carrier on a side opposite to a side from which a first carrier is removed.

FIG. 11 illustrates a step of electrically testing a semiconductor package.

FIG. 12 illustrates a step of forming a redistribution layer structure on a molding material, a first semiconductor die, and a second semiconductor die.

FIG. 13 illustrates a step of forming an external connection structure on a redistribution layer structure.

FIG. 14 illustrates a step of removing (de-bonding) a second carrier.

### DETAILED DESCRIPTION

Hereinafter, an embodiment of the present invention will be described more fully with reference to the accompanying drawings for a person of ordinary skill to easily implement. As those skilled in the art would realize, the described embodiments may be modified in various different ways, all without departing from the spirit or scope of the present invention.

The drawings and description are to be regarded as illustrative in nature and not restrictive. Like reference numerals may designate like elements throughout the specification.

Throughout the specification, when it is described that a part is “connected (in contact with, coupled)” to another part, the part may be “directly connected” to the other element or “connected” to the other part through a third part.

It will be understood that when an element such as a layer, film, region, or substrate is referred to as being “on” another element, it can be directly on the other element or intervening elements may also be present.

Hereinafter, a semiconductor package and a manufacturing method of a semiconductor package according to an embodiment will be described with reference to accompanying drawings.

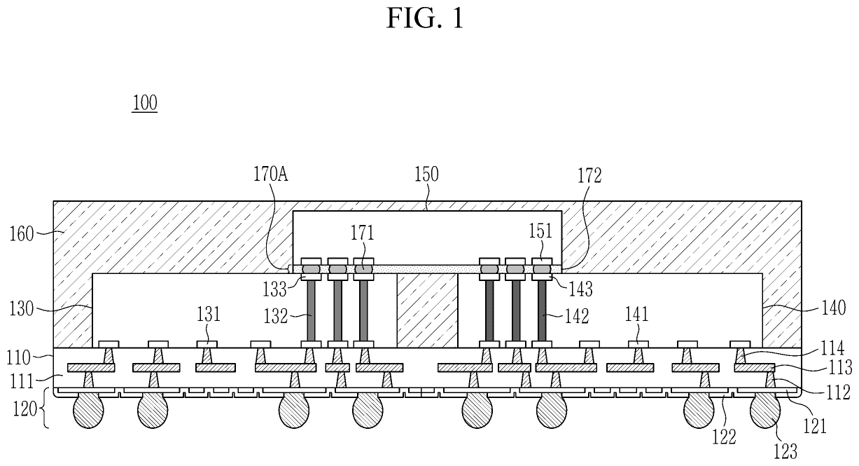

FIG. 1 is a cross-sectional view of a semiconductor package 100 in which a bridge die 150 is electrically and physically connected to a first semiconductor die 130 and a second semiconductor die 140 thereunder by a connection member 171.

Referring to FIG. 1, in an embodiment, a semiconductor package 100 includes a redistribution layer structure 110, a first semiconductor die 130, a second semiconductor die 140, a bridge die 150, a molding material 160, an interconnection structure 170A, and an external connection structure 120.

The redistribution layer structure 110 includes a dielectric layer 111, and first redistribution vias 112, first redistribution lines 113, and second redistribution vias 114 that are disposed in the dielectric layer 111. In an embodiment, the redistribution layer structure that includes a smaller or larger number of the redistribution lines and the redistribution vias is included in the scope of present disclosure.

The dielectric layer 111 protects and insulates the first redistribution vias 112, the first redistribution lines 113, and the second redistribution vias 114. The molding material 160, the first semiconductor die 130, and the second semiconductor die 140 are disposed on the upper surface of the dielectric layer 111. In an embodiment, the level of the upper surface of the dielectric layer 111 and the level of the bottom surface of the molding material 160, the level of the bottom surface of the first semiconductor die 130, and the level of the bottom surface of the second semiconductor die 140 are coplanar.

The first redistribution via 112 is disposed between the first redistribution line 113 and a conductive pad 121 of the external connection structure 120. The first redistribution via 112 electrically connects the first redistribution line 113 and the conductive pad 121 in the vertical direction. The first redistribution line 113 is disposed between the first redistribution via 112 and the second redistribution via 114. The first redistribution line 113 electrically connects the first redistribution via 112 and the second redistribution via 114 in the horizontal direction. The second redistribution via 114 is disposed between the first redistribution line 113 and a lower connection pad 131 of the first semiconductor die 130, and between the first redistribution line 113 and a lower connection pad 141 of the second semiconductor die 140. The second redistribution via 114 electrically connects in the vertical direction the first redistribution line 113 and the lower connection pad 131 of the first semiconductor die 130, and the first redistribution line 113 and the lower connection pad 141 of the second semiconductor die 140. The second redistribution via 114 is directly connected to the lower connection pad 131 of the first semiconductor die 130 without other connection members, and is directly connected to the lower connection pad 141 of the second semiconductor die 140 without other connection members. In an embodiment, an uppermost width of the first redistribution via 112 and the second redistribution via 114 is less than a lowermost width of the first redistribution via 112 and the second redistribution via 114.

The first semiconductor die 130 includes first semiconductor chips, through silicon vias (TSVs) 132, lower connection pads 131, and upper connection pads 133. In an embodiment, the first semiconductor die 130 includes an application processor (AP). In an embodiment, the first semiconductor chip is one of a central processing unit (CPU), a graphics processing unit (GPU), a memory, a controller, a codec, a sensor, or a communication chip. The through silicon via (TSV) 132 is disposed between the lower connection pad 131 and the upper connection pad 133. The through silicon via (TSV) 132 electrically connects the lower connection pad 131 and the upper connection pad 133. In an embodiment, the through silicon via (TSV) 132 includes at least one of tungsten, aluminum, copper, or alloys thereof. The lower connection pad 131 and the upper connection pad 133 include at least one of copper, aluminum, silver, tin, gold, nickel, lead, titanium, or alloys thereof, respectively.

The second semiconductor die 140 includes second semiconductor chips, through silicon vias (TSVs) 142, lower connection pads 141, and upper connection pads 143. In an embodiment, the second semiconductor die 140 includes an AP. In an embodiment, the second semiconductor chip is one of a central processing unit (CPU), a graphics processing unit (GPU), a memory, a controller, a codec, a sensor, or a communication chip. The through silicon via (TSV) 142 is disposed between the lower connection pad 141 and the upper connection pad 143. The through silicon via (TSV) 142 electrically connects the lower connection pad 141 and the upper connection pad 143. In an embodiment, the through silicon via (TSV) 142 includes at least one of tungsten, aluminum, copper, or alloys thereof. The lower connection pad 141 and the upper connection pad 143 include at least one of copper, aluminum, silver, tin, gold, nickel, lead, titanium, or alloys thereof, respectively.

In the semiconductor package 100 according to an embodiment, since the bridge die 150 is spaced apart from the redistribution layer structure 110 that transmits signals and power, the through silicon vias (TSVs) 132, 142 are disposed in the first semiconductor die 130 and the second semiconductor die 140 and are connected to the bridge die 150, thereby receiving the signals and power of the bridge die 150 and increasing a response speed.

The bridge die 150 is disposed on the first semiconductor die 130 and the second semiconductor die 140. In an embodiment, the bridge die 150 is disposed on a part of the upper surface of the first semiconductor die 130 and on a part of the upper surface of the second semiconductor die 140. The bridge die 150 electrically connects the first semiconductor die 130 and the second semiconductor die 140. Accordingly, the first semiconductor die 130 and the second semiconductor die 140 can mutually exchange signals through the bridge die 150. The bridge die 150 includes a connection pad 151. The connection pad 151 is electrically connected to the connection member 171 of the interconnection structure 170A. In an embodiment, the bridge die 150 includes a silicon bridge layer. In an embodiment, the bridge die 150 includes a memory semiconductor chip or a high bandwidth memory (HBM). In an embodiment, connection pad 151 includes at least one of copper, aluminum, silver, tin, gold, nickel, lead, titanium, or alloys thereof.

The interconnection structure 170A is disposed between the first semiconductor die 130 and the bridge die 150, and between the second semiconductor die 140 and the bridge die 150. The interconnection structure 170A includes connection members 171 and an insulating member 172. The connection member 171 electrically connects the upper connection pad 133 of the first semiconductor die 130 and the connection pad 151 of the bridge die 150, and the upper connection pad 143 of the second semiconductor die 140 and the connection pad 151 of the bridge die 150. In an embodiment, the connection member 171 includes a micro bump. The insulating member 172 encloses and protects the connection member 171 between the first semiconductor die 130 and the bridge die 150, and between the second semiconductor die 140 and the bridge die 150. In an embodiment, the insulating member 172 includes a molded under-fill (MUF). In an embodiment, the insulating member 172 includes a non-conductive film (NCF).

The external connection structure 120 is disposed on the bottom surface of the redistribution layer structure 110. The external connection structure 120 includes conductive pads 121, an insulation layer 122, and external connection members 123. The conductive pad 121 electrically connects the first redistribution via 112 of the redistribution layer structure 110 and the external connection member 123. The insulation layer 122 includes a plurality of openings for soldering. The insulation layer 122 prevents the external connection member 123 from being short-circuited. The external connection member 123 electrically connects the semiconductor package 100 to an external device.

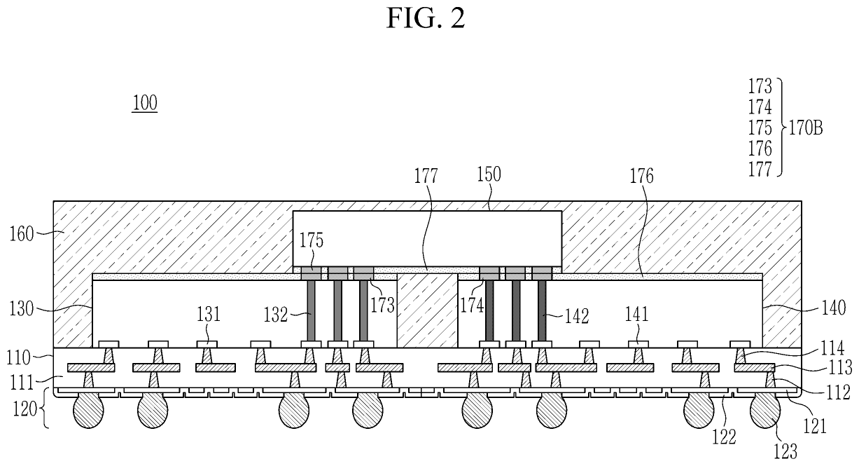

FIG. 2 is a cross-sectional view of a semiconductor package 100 in which a bridge die 150 is electrically and physically connected to a first semiconductor die 130 and a second semiconductor die 140 thereunder by a hybrid bonding.

Referring to FIG. 2, in an embodiment, the semiconductor package 100 includes a redistribution layer structure 110, a first semiconductor die 130, a second semiconductor die 140, a bridge die 150, a molding material 160, an interconnection structure 170B, and an external connection structure 120. The structure of the redistribution layer structure 110, the first semiconductor die 130, the second semiconductor die 140, the bridge die 150, the molding material 160, and the external connection structure 120, are substantially the same as those described with reference to FIG. 1, and a repeated description thereof will be summarized or omitted below.

The first semiconductor die 130 and the second semiconductor die 140 in semiconductor package 100 are bonded to the bridge die 150 by hybrid bonding. Hybrid bonding is a method of bonding two devices by fusing the same materials of the two devices using the bonding properties of the same material. Here, hybrid means that two different types of bonding are performed, such as bonding two devices by bonding between metal-metal of the first type and bonding between non-metal and non-metal of the second type.

According to hybrid bonding, an I/O having a fine pitch can be formed.

The interconnection structure 170B includes first bonding pads 173 and 174 and a first insulation layer 176 on the upper surfaces of the first semiconductor die 130 and the second semiconductor die 140, and second bonding pads 175 and a second insulation layer 177 on the bottom surface of the bridge die 150. The first bonding pads 173 and 174 are directly bonded to the second bonding pad 175 by a metal-metal hybrid bonding, and the first insulation layer 176 is directly boned to the second insulation layer 177 by a non-metal-non-metal hybrid bonding.

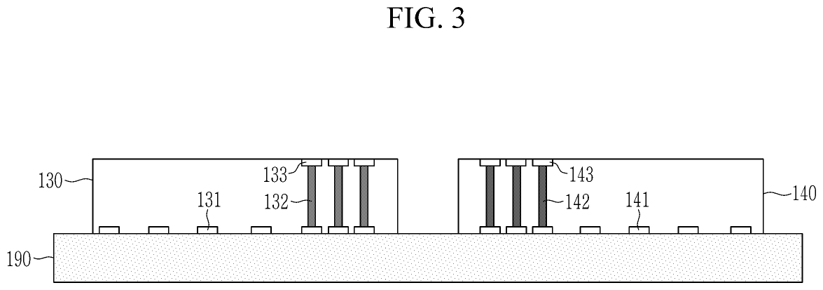

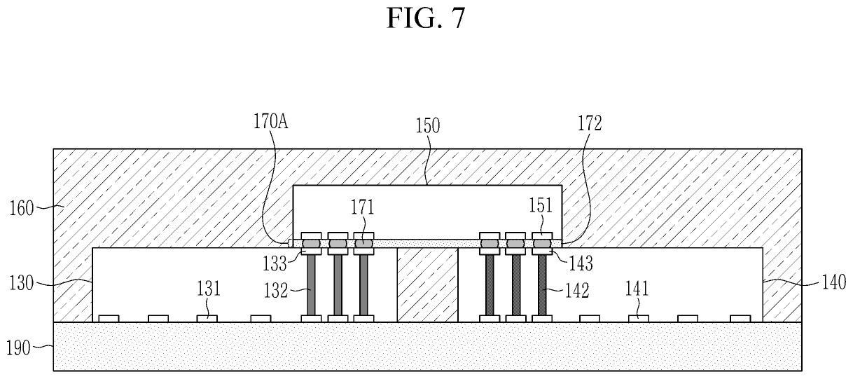

FIG. 3 illustrates a step of mounting a first semiconductor die 130 and a second semiconductor die 140 on a first carrier 190 as one of steps of a semiconductor package manufacturing method. FIG. 3 to FIG. 5, and FIG. 7 to FIG. 14, are cross-sectional views that illustrate steps of a manufacturing method of a semiconductor package of FIG. 1.

Referring to FIG. 3, in an embodiment, the first semiconductor die 130 and the second semiconductor die 140 are mounted on the first carrier 190. The first carrier 190 includes, for example, a silicon-based material such as glass or a silicon oxide, an organic material, or another material such as aluminum oxide, any combination of these materials, etc. The first semiconductor die 130 and the second semiconductor die 140 are disposed side by side and horizontally at the same level. The active surfaces of the first semiconductor die 130 and the second semiconductor die 140 face the first carrier 190. In an embodiment, the first semiconductor die 130 and the second semiconductor die 140 are attached onto the first carrier 190 by a laser.

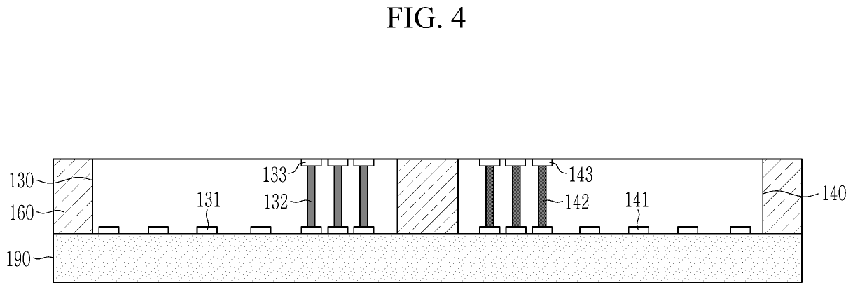

FIG. 4 illustrates a step of molding a first semiconductor die 130 and a second semiconductor die 140 on a first carrier 190 as one of steps of a semiconductor package manufacturing method.

Referring to FIG. 4, in an embodiment, on the first carrier 190, the first semiconductor die 130 and the second semiconductor die 140 are molded by the molding material 160. The first semiconductor die 130 and the second semiconductor die 140 are molded by the molding material 160, which conformally fixes the first semiconductor die 130 and the second semiconductor die 140. Accordingly, the bonding of the following bridge die 150 to the first semiconductor die 130 and the second semiconductor die 140 can be accurately performed. In an embodiment, a molding process that uses the molding material 160 includes a compression molding process or a transfer molding process. In an embodiment, the molding material 160 is formed of a thermosetting resin such as an epoxy resin. In an embodiment, the molding material 160 is an epoxy molding compound (EMC).

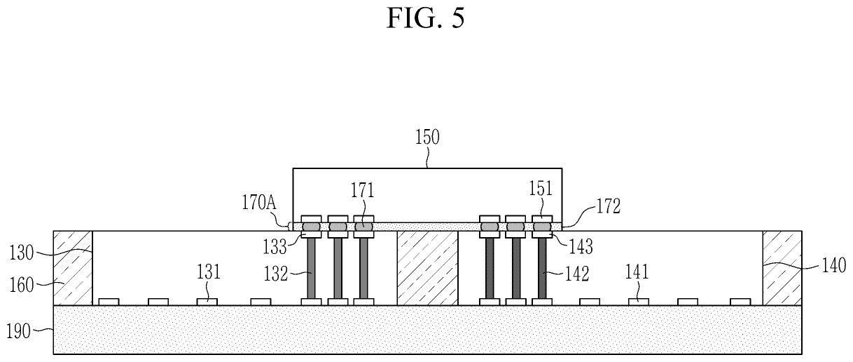

FIG. 5 illustrates a step of mounting a bridge die 150 on a first semiconductor die 130 and a second semiconductor die 140 by using a connecting member 171 as one of steps of a semiconductor package manufacturing method.

Referring to FIG. 5, in an embodiment, the bridge die 150 is mounted on the first semiconductor die 130 and the second semiconductor die 140 by using the connection member 171. The active surface of bridge die 150 faces the first semiconductor die 130 and the second semiconductor die 140. The upper connection pad 133 of the first semiconductor die 130 and the connection pad 151 of the bridge die 150 are electrically connected by using the connection member 171, and the upper connection pad 143 of the second semiconductor die 140 and the connection pad 151 of the bridge die 150 are electrically connected by using the connection member 171. In an embodiment, the connection member 171 includes a micro bump. In an embodiment, the connection member 171 includes at least one of tin, silver, lead, nickel, copper, or alloys thereof.

The insulating member 172 is disposed between the first semiconductor die 130 and the bridge die 150, and between the second semiconductor die 140 and the bridge die 150 to surround the connection members 171. For example, by disposing the insulating member 172, stress between the first semiconductor die 130 and the bridge die 150, and between the second semiconductor die 140 and the bridge die 150 is alleviated.

In an embodiment, before mounding the bridge die 150 on the first semiconductor die 130 and the second semiconductor die 140, a non-conductive film (NCF) as the insulating member 172 is attached on the molding material 160, the first semiconductor die 130, and the second semiconductor die 140. The non-conductive film (NCF) is adhesive and adheres onto the molding material 160, the first semiconductor die 130, and the second semiconductor die 140. The non-conductive film (NCF) has an uncured state that can be deformed by an external force. The non-conductive film (NCF) is attached by heating at a temperature of about 170° C. to about 300° C. for about 1 second to about 20 seconds. The bridge die 150 is stacked on the non-conductive film (NCF). The connection member 171 provided in the bridge die 150 can pass through the non-conductive film (NCF) to contact the upper connection pad 133 of the first semiconductor die 130 and the upper connection pad 143 of the second semiconductor die 140.

In an embodiment, after bonding the bridge die 150 onto the molding material 160, the first semiconductor die 130 and the second semiconductor die 140 by using the connection member 171, an MUF (Molded Under-Fill) is filled between the bridge die 150, the molding material 160, the first semiconductor die 130 and the second semiconductor die 140.

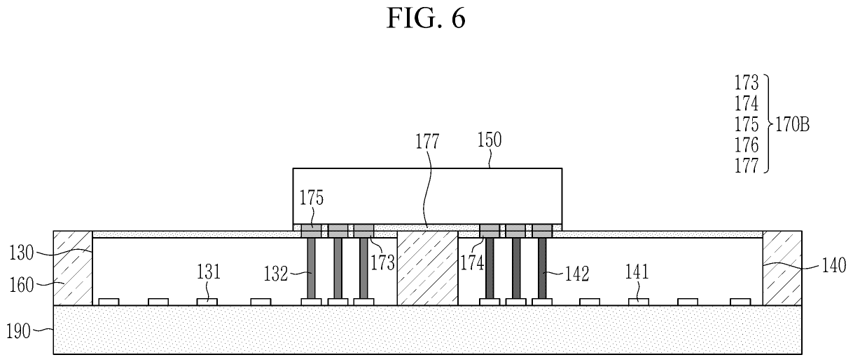

FIG. 6 illustrates a step of bonding a bridge die 150 on a first semiconductor die 130 and a second semiconductor die 140 by performing hybrid bonding as one of steps of a semiconductor package manufacturing method. FIG. 6 illustrates bonding a first semiconductor die 130 and a second semiconductor die 140 and a bridge die 150 by a hybrid bonding in a semiconductor package of FIG. 2. Other steps of a semiconductor package manufacturing method of FIG. 2 are substantially similar to steps of a semiconductor package manufacturing method shown and described in FIG. 3 to FIG. 5 and FIG. 7 to FIG. 14.

Referring to FIG. 6, in an embodiment, the bridge die 150 is bonded on the first semiconductor die 130 and the second semiconductor die 140 by performing hybrid bonding. The active surface of the bridge die 150 faces the first semiconductor die 130 and the second semiconductor die 140.

The first bonding pad 173 on the upper surface of the first semiconductor die 130 and the second bonding pad 175 on the bottom surface of the bridge die 150, the first bonding pad 174 on the upper surface of the second semiconductor die 140 and the second bonding pad 175 on the bottom surface of the bridge die 150 are directly bonded by the metal-metal hybrid bonding. Metal-metal hybrid bonding refers to a process in which the metal bonding is formed in the interface between the first bonding pad 173 on the upper surface of the first semiconductor die 130 and the second bonding pad 175 on the bottom surface of the bridge die 150, and between the first bonding pad 174 on the upper surface of the second semiconductor die 140 and the second bonding pad 175 on the bottom surface of the bridge die 150. In an embodiment, the first bonding pads 173 and 174 and the second bonding pad 175 include copper. In an embodiment, the first bonding pads 173 and 174 and the second bonding pad 175 are a metallic material that can apply hybrid bonding.

The first bonding pad 173 on the upper surface of the first semiconductor die 130 and the second bonding pad 175 on the bottom surface on the bridge die 150, and the first bonding pad 174 on the upper surface of the second semiconductor die 140 and the second bonding pad 175 on the bottom surface of the bridge die 150, are formed of the same material, and after the hybrid bonding, the interface between the first bonding pad 173 and the second bonding pad 175 and between the first bonding pad 174 and the second bonding pad 175 disappears. The first semiconductor die 130 and the bridge die 150, and the second semiconductor die 140 and the bridge die 150 are electrically connected to each other through the first bonding pad 173 and the second bonding pad 175, and through the first bonding pad 174 and the second bonding pad 175.

The first insulation layer 176 on the upper surface of the first semiconductor die 130 and the upper surface of the second semiconductor die 140 and the second insulation layer 177 on the bottom surface of the bridge die 150 are directly bonded by the non-metal-non-metal hybrid bonding. Covalent bonding occurs on the interfaces between the first insulation layer 176 on the upper surface of the first semiconductor die 130 and the upper surface of the second semiconductor die 140 and the second insulation layer 177 on the bottom surface of the bridge die 150, by the non-metal-non-metal hybrid bonding.

In an embodiment, the first insulation layer 176 and the second insulation layer 177 include a silicon oxide or a TEOS formation oxide. In an embodiment, the first insulation layer 176 and the second insulation layer 177 include SiO₂. In an embodiment, the first insulation layer 176 and the second insulation layer 177 each include one of a silicon nitride, a silicon oxynitride, or another appropriate dielectric material. In an embodiment, the first insulation layer 176 and the second insulation layer 177 each include SiN or SiCN.

The first insulation layers 176 and the second insulation layer 177 are formed of the same material, and after the hybrid bonding, the interfaces between the first insulation layers 176 and the second insulation layer 177 disappear.

FIG. 7 illustrates a step of molding a first semiconductor die 130, a second semiconductor die 140, and a bridge die 150 on a first carrier 190 as one of steps of a semiconductor package manufacturing method.

Referring to FIG. 7, in an embodiment, on the first carrier 190, the first semiconductor die 130, the second semiconductor die 140, and the bridge die 150 are molded by a molding material 160. In an embodiment, the molding material 160 in FIG. 7 is the same molding material as the molding material 160 in FIG. 4. In an embodiment, the molding material 160 in FIG. 7 is a different molding material from the molding material 160 in FIG. 4. In an embodiment, the process of molding by the molding material 160 includes a compression molding or a transfer molding process. In an embodiment, the molding material 160 is formed of a thermosetting resin such as an epoxy resin. In an embodiment, the molding material 160 is an epoxy molding compound (EMC).

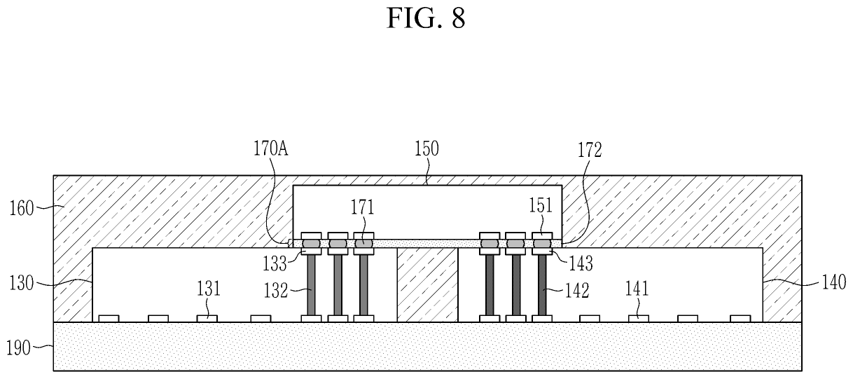

FIG. 8 illustrates a step of planarizing an upper surface of a molding material 160 as one of steps of a semiconductor package manufacturing method.

Referring to FIG. 8, in an embodiment, a chemical mechanical polishing (CMP) is performed to level the upper surface of the molding material 160. The upper surface of the molding material 160 is planarized by applying a CMP process.

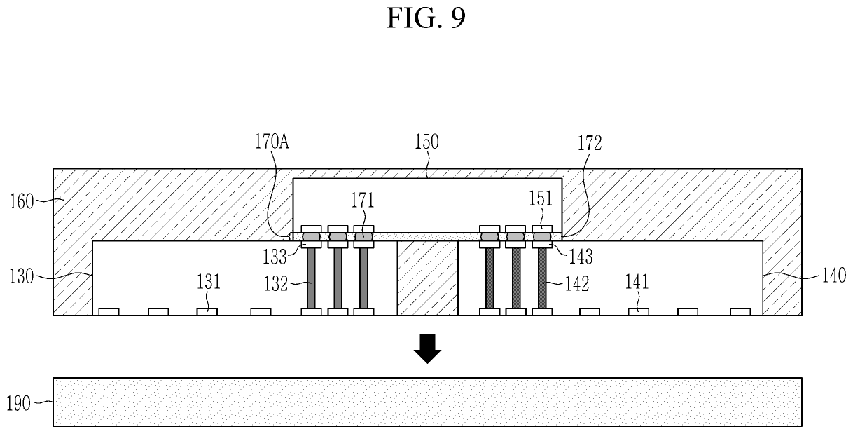

FIG. 9 illustrates a step of removing (de-bonding) a first carrier 190 as one of steps of a semiconductor package manufacturing method.

Referring to FIG. 9, in an embodiment, the first carrier 190 is removed from the bottom surfaces of the first semiconductor die 130 and the second semiconductor die 140, and from the bottom surface of the molding material 160.

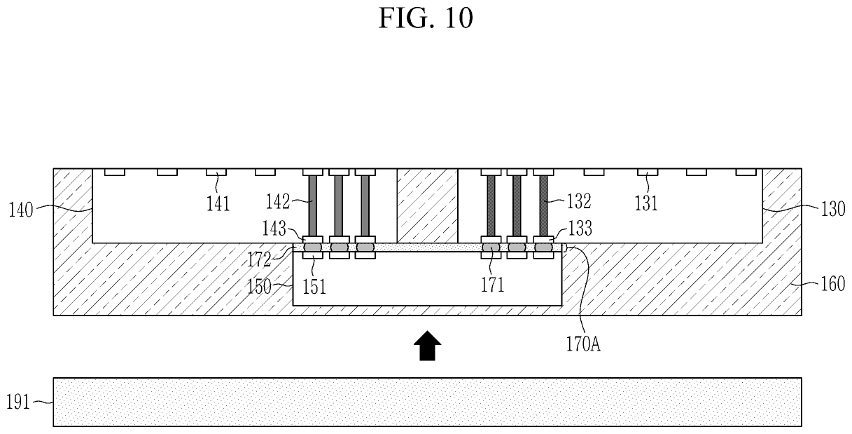

FIG. 10 illustrates a step of bonding a second carrier 191 on a side opposite to a side from which a first carrier 190 is removed as one of steps of a semiconductor package manufacturing method.

Referring to FIG. 10, in an embodiment, an intermediate product of the first semiconductor die 130, the second semiconductor die 140, and the bridge die 150 molded in the molding material 160 is turned over, and the second carrier 191 is bonded onto the side opposite to the side from which the first carrier 190 was removed. The second carrier 191 includes, for example, at least one of a silicon-based material such as glass or a silicon oxide, an organic material, or another material such as aluminum oxide, or any combination of these materials, etc.

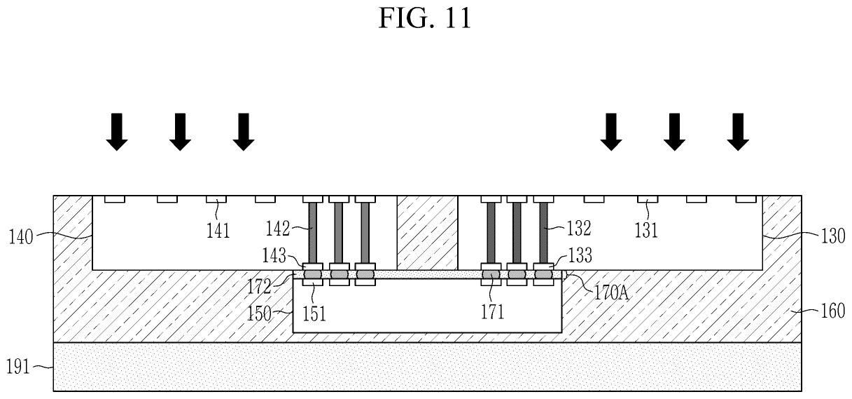

FIG. 11 illustrates a step of electrically testing a semiconductor package 100 as one of steps of a semiconductor package manufacturing method.

Referring to FIG. 11, in an embodiment, before forming the redistribution layer structure 110, a probe test is performed to confirm whether the first semiconductor die 130, the second semiconductor die 140, and the bridge die 150 in the molding material 160 function as semiconductor dies in terms of electrical characteristics and reliability.

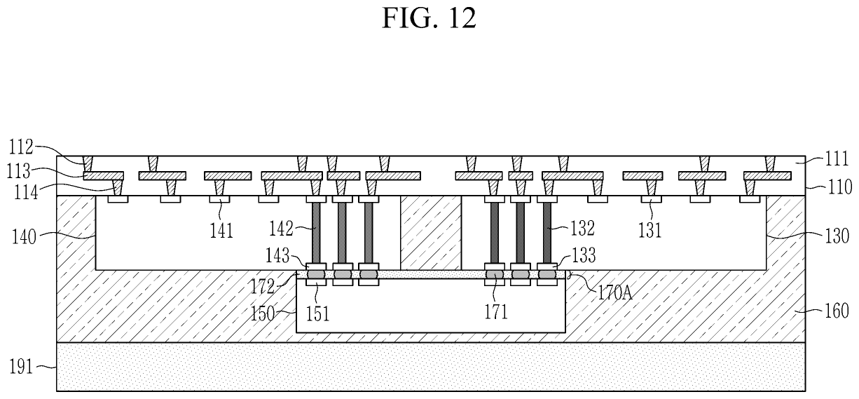

FIG. 12 illustrates a step of forming a redistribution layer structure 110 on the molding material 160, the first semiconductor die 130, and the second semiconductor die 140 as one of steps of a semiconductor package manufacturing method.

Referring to FIG. 12, in an embodiment, the redistribution layer structure 110 is formed on the molding material 160, the first semiconductor die 130, and the second semiconductor die 140.

The dielectric layer 111 is formed on the molding material 160, the first semiconductor die 130, and the second semiconductor die 140. The dielectric layer 111 is directly formed on the molding material 160, the first semiconductor die 130, and the second semiconductor die 140, so a connection member such as a micro bump or a solder bump, etc., is not used. In an embodiment, the dielectric layer 111 includes a photosensitive polymer layer. A photosensitive polymer can form fine patterns in a photolithography process.

In an embodiment, the dielectric layer 111 includes a photoimageable dielectric (PID) used in a redistribution process. In an embodiment, the photoimageable dielectric (PID) includes at least one of a polyimide-based photosensitive polymer, a novolac-based photosensitive polymer, polybenzoxazole, a silicon-based polymer, an acrylate-based polymer, or an epoxy-based polymer. In an embodiment, the dielectric layer 111 is formed of polymer such as a PBO and/or a polyimide, etc. In an embodiment, the dielectric layer 111 is formed of an inorganic dielectric material such as a silicon nitride or a silicon oxide, etc. In an embodiment, the dielectric layer 111 is formed by one of a CVD, an ALD, or a PECVD process.

After forming the dielectric layer 111, the dielectric layer 111 is selectively etched to form via holes, and a conducting material is filled in the via holes to form the second redistribution vias 114. Since the redistribution layer structure 110 is formed by inverting the intermediate products of the first semiconductor die 130, the second semiconductor die 140, and the bridge die 150 molded in the molding material 160, the uppermost width of each second redistribution vias 114 is larger than the width of the lowermost part. Thus, in the final product, the width of the uppermost part of each second redistribution via of the second redistribution vias 114 is less than the width of the lowermost part of that.

The dielectric layer 111 is additionally deposited on the second redistribution vias 114 and the dielectric layer 111, and the additionally deposited dielectric layer 111 is selectively etched to form openings, and a conducting material is filled in the openings to form the first redistribution lines 113.

The dielectric layer 111 is additionally deposited on the first redistribution lines 113 and the dielectric layer 111, the additionally deposited dielectric layer 111 is selectively etched to form via holes, and the via holes are filled with a conducting material to form the first redistribution vias 112. For the same reason as the second redistribution vias 114, in the final product, the width of the uppermost part of each second redistribution vias 112 is less than the width of the lowermost part.

In an embodiment, the first redistribution vias 112, the first redistribution lines 113, and the second redistribution vias 114 include at least one of copper, aluminum, tungsten, nickel, gold, tin, titanium, or alloys thereof. In an embodiment, the first redistribution vias 112, the first redistribution lines 113, and the second redistribution vias 114 are formed by a sputtering process. In an embodiment, the first redistribution vias 112, the first redistribution lines 113, and the second redistribution vias 114 are formed by forming a seed metal layer and performing an electroplating process.

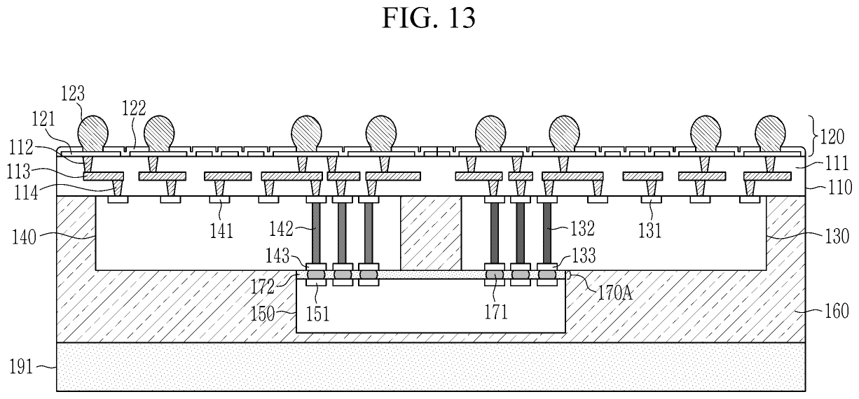

FIG. 13 illustrates a step of forming an external connection structure 120 on a redistribution layer structure 110 as one of steps of a semiconductor package manufacturing method.

Referring to FIG. 13, in an embodiment, an external connection structure 120 is formed on the redistribution layer structure 110. An insulation layer 122 is formed on the dielectric layer 111 of the redistribution layer structure 110, conductive pads 121 are formed on the first redistribution vias 112 and external connection members 123 are formed on the conductive pads 121. In an embodiment, the conductive pad 121 includes at least one of copper, nickel, zinc, gold, silver, platinum, palladium, chromium, titanium, or alloys thereof. In an embodiment, the insulation layer 122 includes a solder resist. In an embodiment, the external connection member 123 includes at least one of tin, silver, lead, nickel, copper, or alloys thereof. In an embodiment, the conductive pad 121 are formed by performing one of a sputtering process, or an electroplating process after forming a seed metal layer. In an embodiment, the insulation layer 122 is formed by one of a CVD, ALD, or PECVD process.

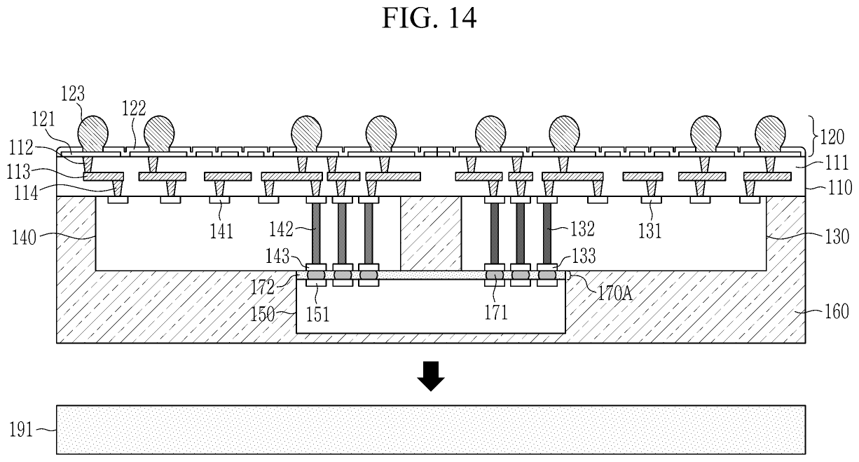

FIG. 14 illustrates a step of removing (de-bonding) a second carrier 191 as one of steps of a semiconductor package manufacturing method.

Referring to FIG. 14, in an embodiment, the second carrier 191 is removed from the bottom surface of the molding material 160.

While embodiments of this disclosure have been described in connection with what is presently considered to be practical embodiments, it is to be understood that embodiments of the disclosure are not limited to the disclosed embodiments. On the contrary, it is intended to cover various modifications and equivalent arrangements included within the spirit and scope of the appended claims.

What is claimed is:

1. A semiconductor package, comprising:
a redistribution layer structure;
a first semiconductor die and a second semiconductor die disposed on the redistribution layer structure;
a bridge die disposed on the first semiconductor die and the second semiconductor die and that electrically connects the first semiconductor die and the second semiconductor die to each other; and
a molding material that molds the first semiconductor die, the second semiconductor die, and the bridge die onto the redistribution layer structure,
wherein a bottom surface of the first semiconductor die and a bottom surface of the second semiconductor die are coplanar with an upper surface of the redistribution layer structure.

2. The semiconductor package of claim 1, wherein
the first semiconductor die and the second semiconductor die exchange signals through the bridge die.

3. The semiconductor package of claim 1, wherein
the bridge die is disposed on a part of an upper surface of the first semiconductor die and a part of an upper surface of the second semiconductor die.

4. The semiconductor package of claim 1, wherein:
the redistribution layer structure includes a plurality of redistribution vias,
the first semiconductor die and the second semiconductor die each include a plurality of connection pads at a lowest level, and
each redistribution via of an uppermost level of the plurality of redistribution vias is directly bonded with a corresponding connection pad of the plurality of connection pads.

5. The semiconductor package of claim 1, wherein:
the redistribution layer structure includes a plurality of redistribution vias, and
an uppermost width of each redistribution via of the plurality of redistribution vias is less than a lowermost width thereof.

6. The semiconductor package of claim 1, wherein
the first semiconductor die and the second semiconductor die each include an application processor (AP).

7. The semiconductor package of claim 1, wherein
the bridge die includes a memory semiconductor.

8. A semiconductor package, comprising:
a redistribution layer structure;
a first semiconductor die and a second semiconductor die disposed on the redistribution layer structure;
an interconnection structure disposed on the first semiconductor die and the second semiconductor die;
a bridge die disposed on the interconnection structure, wherein the interconnection structure electrically connects the bridge die and the first semiconductor die and the bridge die and the second semiconductor die, and the bridge die electrically connects the first semiconductor die and the second semiconductor die to each other; and
a molding material disposed on the redistribution layer structure and that molds the first semiconductor die, the second semiconductor die, and the bridge die,
wherein bottom surfaces of the first semiconductor die and the second semiconductor die are coplanar with an upper surface of the redistribution layer structure.

9. The semiconductor package of claim 8, wherein
the interconnection structure includes a micro bump.

10. The semiconductor package of claim 9, wherein
the interconnection structure includes an insulating member that surrounds the micro bump.

11. The semiconductor package of claim 10, wherein
the insulating member includes a molded under-fill (MUF).

12. The semiconductor package of claim 8, wherein
the interconnection structure includes:
a plurality of first bonding pads and a first insulation layer disposed on upper surfaces of the first semiconductor die and the second semiconductor die; and
a plurality of second bonding pads and a second insulation layer disposed on a bottom surface of the bridge die.

13. The semiconductor package of claim 12, wherein
each first bonding pad of the plurality of first bonding pads is directly bonded to a corresponding second bonding pad of the plurality of second bonding pads.

14. The semiconductor package of claim 13, wherein
the first bonding pad and the second bonding pad each include copper.

15. The semiconductor package of claim 12, wherein
the first insulation layer is directly bonded with the second insulation layer.

16. The semiconductor package of claim 15, wherein
the first insulation layer and the second insulation layer each include at least one of a silicon oxide, a silicon nitride, or a silicon oxynitride.

17. The semiconductor package of claim 8, wherein:
the first semiconductor die and the second semiconductor die each include a plurality of through silicon vias (TSVs), respectively, and
the plurality of through silicon vias electrically connect the interconnection structure and the redistribution layer structure.

18. A manufacturing method of a semiconductor package, comprising;
attaching a first semiconductor die and a second semiconductor die side by side on a carrier;
molding the first semiconductor die and the second semiconductor die on the carrier;
bonding a bridge die onto the first semiconductor die and the second semiconductor die;
molding the bridge die; and
forming a redistribution layer structure on bottom surfaces of the first semiconductor die and the second semiconductor die,
wherein the bottom surface of the first semiconductor die and the second semiconductor die are coplanar with an upper surface of the redistribution layer structure.

19. The manufacturing method of the semiconductor package of claim 18, wherein
bonding the bridge die onto the first semiconductor die and the second semiconductor die is performed by hybrid bonding.

20. The manufacturing method of the semiconductor package of claim 18, further comprising
removing the carrier and performing a probe test before forming the redistribution layer structure on the bottom surfaces of the first semiconductor die and the second semiconductor die.
